(19) United States
(12) Patent Application Publication
(10) Pub. No.: US 2010/0193767 A1
(43) Pub. Date: Aug. 5, 2010

(54) ENCAPSULATED NANOPARTICLES

(76) Inventors: Imad Naasani, Manchester (GB); Mark Christopher McCairn, Newent (GB)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/700,253

(22) Filed: Feb. 4, 2010

Related U.S. Application Data
(60) Provisional application No. 61/152,332, filed on Feb. 13, 2009.

(30) Foreign Application Priority Data
Feb. 5, 2009 (GB) GB 0901857.3

(51) Int. Cl. H01L 29/66; H01L 21/31

(52) U.S. Cl. 257/9; 438/780; 257/E29.168; 257/E21.24; 977/774

(57) ABSTRACT

A nanoparticle composition including a semiconductor nanoparticle encapsulated within a self-assembled layer including an amphiphilic cross-linkable multi-unsaturated fatty acid based compound or derivative thereof. In other embodiments, a nanoparticle composition includes a semiconductor nanoparticle encapsulated within a self-assembled layer including an amphiphilic cross-linkable C₈-C₃₆ diacetylene based compound or derivative thereof.

### RELATED APPLICATIONS

This application claims the benefit of and priority to co-pending application GB 0901857.3 filed Feb. 5, 2009 and U.S. Provisional Patent Application Ser. No. 61/152,332 filed Feb. 13, 2009, the disclosures of which are incorporated herein by reference in their entireties.

### FIELD OF THE INVENTION

The present invention relates to nanoparticle compositions including encapsulated semiconductor nanoparticles and methods for their production, particularly, but not exclusively, core, core/shell or core/multishell semiconductor nanoparticles which, as a result of their encapsulation can be substantially dispersed or dissolved in aqueous media and/or adapted for used in applications such as biolabelling, biosensing and the like.

### BACKGROUND

Fluorescent organic molecules typically suffer from disadvantages that include photo-bleaching, different excitation irradiation frequencies and broad emissions. However, the substitution of fluorescent organic molecules with quantum dot (QD) semiconductor nanoparticles circumvents these limitations.

The size of a semiconductor nanoparticle dictates the electronic properties of the material; the band gap energy being inversely proportional to the size of the semiconductor nanoparticles as a consequence of quantum confinement effects. Different sized QDs may be excited by irradiation with a single wavelength of light to give a discrete fluorescence emission of narrow band width. Further, the large surface-area-to-volume ratio of the nanoparticle has a profound impact upon the physical and chemical properties of the QD.

Nanoparticles that include a single semiconductor material usually have modest physical/chemical stability and consequently relatively low fluorescence quantum efficiencies. These low quantum efficiencies arise from non-radiative electron-hole recombinations that occur at defects and dangling bonds at the surface of the nanoparticle.

Core-shell nanoparticles may include a semiconductor core with a shell material of typically wider band-gap and similar lattice dimensions grown epitaxially on the surface of the core. The shell eliminates defects and dangling bonds from the surface of the core, which confines charge carriers within the core and away from surface states that may function as centres for non-radiative recombination. More recently, the architecture of semiconductor nanoparticles has been further developed to include core/multishell nanoparticles in which the core semiconductor material is provided with two or more shell layers to further enhance the physical, chemical and/or optical properties of the nanoparticles.

The surfaces of core and core/(multi)shell semiconductor nanoparticles often possess highly reactive dangling bonds, which may be passivated by coordination of a suitable ligand, such as an organic ligand compound. The ligand compound is typically either dissolved in an inert solvent or employed as the solvent in the nanoparticle core growth and/or shelling procedures that are used to synthesise the QDs. Either way, the ligand compound chelates the surface of the QD by donating lone pair electrons to the surface metal atoms, which inhibits aggregation of the particles, protects the particle from its surrounding chemical environment, provides electronic stabilisation, and may impart solubility in relatively non-polar media.

One factor which has previously restricted the widespread application of QDs in aqueous environments (i.e., media including primarily water), for example as biomarkers or in biosensing applications, is the incompatibility of QDs with aqueous media, that is, the inability to form stable systems with QDs dispersed or dissolved in aqueous media. Consequently, a series of surface modification procedures have been developed to render QDs aqueous compatible, i.e., QDs that can disperse homogeneously in water or media including primarily water.

The most widely used procedure to modify the surface of a QD is known as ligand exchange'. Lipophilic ligand molecules that inadvertently coordinate to the surface of the QD during core synthesis and/or shelling procedures may subsequently be exchanged with a polar/charged ligand compound of choice. An alternative surface modification strategy interchelates polar/charged molecules or polymer molecules with the ligand molecules that are already coordinated to the surface of the QD.

Current ligand exchange and interchelation procedures may render the QDs compatible with aqueous media but usually result in materials of lower quantum yield and/or substantially larger size than the corresponding unmodified QD.

Another factor limiting the application of QDs in biolabelling and related applications has been the difficulty in combining acceptable aqueous compatibility with the ability to link or associate the QDs with desired biolabelling species.

Another challenge is ensuring that the QD-containing species carrying the biolabel are both biologically compatible and safe to use.

### SUMMARY

In some embodiments of the present invention, one or more of the above problems may be obviated or mitigated.

According to a first aspect, embodiments of the present invention feature a nanoparticle composition that includes or consists essentially of a semiconductor nanoparticle encapsulated within a self-assembled layer including an amphiphilic cross-linkable multi-unsaturated fatty acid based compound or derivative thereof.

The cross-linkable multi-unsaturated fatty acid may incorporate at least two carbon-carbon double or triple bonds separated by a single carbon-carbon bond. The fatty acid may incorporate a diacetylene moiety, and/or may be associated with the nanoparticle surface via an aliphatic region of the fatty acid. The fatty acid based compound may include a binding group adapted to be able to bind selectively to a target molecule or binding site. The fatty acid based compound may have the formula CH₃(CH₂)ₘ—C≡C—C≡C—(CH₂)ₙ—CO₂X, where m=2 to 20, n=0 to 10, and X is hydrogen or another chemical group (e.g., a hydrophilic group).

The fatty acid based compound may be derived from a fatty acid compound selected from the group consisting of 10,12-Heptacosadiynoic acid, 10,12-Heptadecadiynoic acid, 10,12-Nonacosadiynoic acid, 10,12-Pentacosadiynoic acid, 10,12-Tricosadiynoic acid, 2,4-Heneicosadiynoic acid, 2,4-Heptadecadiynoic acid, 2,4-Nonadecadiynoic acid, and 2,4-Pentadecadiynoic acid. The fatty acid based compound may incorporate a hydrophilic group, which itself may incorporate polyether linkages. The hydrophilic group may be polyethylene glycol or a derivative thereof, and/or include a binding group adapted to be able to bind selectively to a target molecule or binding site.

In a second aspect, embodiments of the present invention feature a nanoparticle composition that includes or consists essentially of a semiconductor nanoparticle encapsulated within a self-assembled layer including an amphiphilic cross-linked fatty acid based polymer or derivative thereof.

The fatty acid based polymer may include or consist essentially of cross-polymerised repeating units derived from a cross-linkable multi-unsaturated fatty acid based compound or derivative thereof. The fatty acid based polymer may incorporate a diacetylene moiety.

In a third aspect, embodiments of the present invention feature a nanoparticle composition that includes or consists essentially of a semiconductor nanoparticle encapsulated within a self-assembled layer including an amphiphilic cross-linkable C₈-C₃₆ diacetylene based compound or derivative thereof.

The diacetylene based compound may incorporate a hydrophilic group, which may be bonded to a terminal carbon atom of the diacetylene compound. The hydrophilic group may be polyethylene glycol or a derivative thereof and/or may incorporate polyether linkages. The diacetylene based compound may include a binding group adapted to be able to bind selectively to a target molecule or binding site.

In a fourth aspect, embodiments of the present invention feature a nanoparticle composition that includes or consists essentially of a semiconductor nanoparticle encapsulated within a self-assembled layer including an amphiphilic cross-linked C₈-C₃₆ diacetylene based polymer or derivative thereof. The diacetylene based polymer may include or consist essentially of cross-polymerised repeating units derived from a cross-linkable C₈-C₃₆ diacetylene based compound or derivative thereof.

In yet another aspect, embodiments of the present invention feature a method for producing a nanoparticle composition that includes or consists essentially of semiconductor nanoparticles encapsulated within a self-assembled layer. The self-assembled layer includes or consists essentially of an amphiphilic cross-linkable multi-unsaturated fatty acid compound or derivative thereof. The semiconductor nanoparticle and the amphiphilic fatty acid based compound are provided. The semiconductor nanoparticles are contacted with the amphiphilic fatty acid based compound under conditions suitable to permit the amphiphilic fatty acid based compound to self-assemble so as to form a self-assembled layer encapsulating or at least partially encapsulating each of the semiconductor nanoparticles.

The fatty acid based compound may be provided in at least a ten-fold molar excess compared to the nanoparticles. The fatty acid based compound may be reacted with a further compound incorporating a hydrophilic group so as to incorporated the hydrophilic group into the fatty acid based compound prior to contacting the nanoparticles with the fatty acid based compound.

In a further aspect, embodiments of the present invention feature a method for producing a nanoparticle composition that includes or consists essentially of a semiconductor nanoparticle encapsulated within a self-assembled layer. The self-assembled layer includes or consists essentially of an amphiphilic cross-linked fatty acid based polymer or derivative thereof. The semiconductor nanoparticle is contacted with the amphiphilic fatty acid based compound, and the amphiphilic fatty acid based compound is polymerised. Polymerisation may be effected by exposing the fatty acid based compound to photoradiation, heat, and/or a chemical polymerising agent.

In another aspect, embodiments of the present invention feature a method for producing a nanoparticle composition that includes or consists essentially of semiconductor nanoparticles encapsulated within a self-assembled layer. The self-assembled layer includes or consists essentially of an amphiphilic cross-linkable C₈-C₃₆ diacetylene based compound or derivative thereof. The semiconductor nanoparticles and the amphiphilic diacetylene based compound are provided. The semiconductor nanoparticles are contacted with the amphiphilic diacetylene based compound under conditions suitable to permit the amphiphilic diacetylene based compound to self-assemble so as to form a self-assembled layer encapsulating or at least partially encapsulating each semiconductor nanoparticle. The diacetylene based compound may be provided in at least a ten-fold molar excess compared to the nanoparticles, and/or may be reacted with a further compound incorporating a hydrophilic group so as to incorporate the hydrophilic group into the diacetylene based compound prior to contacting the nanoparticles with the fatty acid based compound.

In yet another aspect, embodiments of the present invention feature a method for producing a nanoparticle composition that includes or consists essentially of a semiconductor nanoparticle encapsulated within a self-assembled layer. The self-assembled layer includes or consists essentially of an amphiphilic cross-linked C₈-C₃₆ diacetylene based polymer or derivative thereof. The semiconductor nanoparticle is contacted with the amphiphilic diacetylene based compound, and the amphiphilic diacetylene based compound is polymerised. The polymerisation may be effected by exposing the diacetylene based compound to photoradiation, heat, and/or a chemical polymerising agent.

Embodiments of the above-defined aspects of the present invention may provide stable, robust encapsulated nanoparticles that exhibit relatively high quantum yield, and may be appropriately functionalised to enable the nanoparticles to be rendered aqueous compatible and/or linked to further species that may bind to target molecules or binding sites. The nanoparticles may be core, core/shell, or core/multishell nanoparticles.

### BRIEF DESCRIPTION OF THE FIGURES

FIG. 1 is a non-exhaustive list of exemplary diacetylene ligands;

FIG. 2 illustrates the polymerisation of a preferred diacetylene monomer, 10,12 tricosadiynoic acid;

FIG. 3 is a schematic representation of an initial step in the functionalisation of a quantum dot (QD) surface with diacetylene monomers prior to polymerisation;

FIG. 4 is an emission spectrum of InP/ZnS quantum dots bound to a preferred PEGylated polydiacetylene ligand in 50 mM borate buffer at pH 8.5;

FIG. 5 is a normalised plot of the hydrodynamic size of the InP/ZnS quantum dots which provided the results shown in FIG. 4;

FIGS. 6a and 6b are photographs of the sample of InP/ZnS quantum dots analysed to provide the results shown in FIGS. 4 and 5; FIG. 6a was taken under ambient light and FIG. 6b was taken under UV light at 360 nM; and

FIG. 7 is a graph illustrating the particle size dispersity across a population of diacetylene encapsulated quantum dots prepared according to an embodiment of the present invention and then dispersed in a water-based borate buffer.

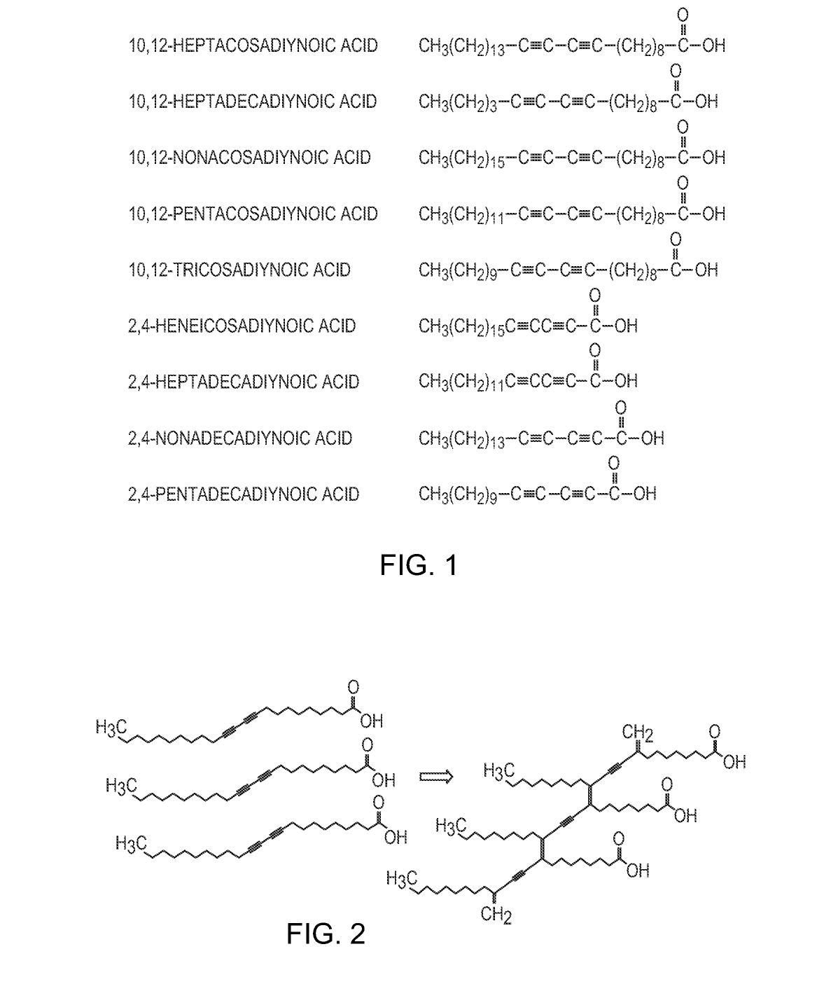

### DETAILED DESCRIPTION

Aqueous compatible quantum dots produced according to aspects of the present invention may be employed in many different applications including, but not limited to, incorporation into polar solvents (e.g., water and water-based solvents), electronic devices, inks, polymers, glasses or attachment of the quantum dot nanoparticles to cells, biomolecules, metals, molecules and the like.

As will be appreciated by the skilled person, the term “amphiphilic” refers to a molecule that possesses both hydrophilic and lipophilic properties. Embodiments of certain aspects of the present invention employ a fatty acid or derivative, which by definition incorporates a lipophilic aliphatic moiety, while embodiments of other aspects of the present invention employ a diacetylene or derivative incorporating a relatively long (C₈-C₃₆) lipophilic carbon chain.

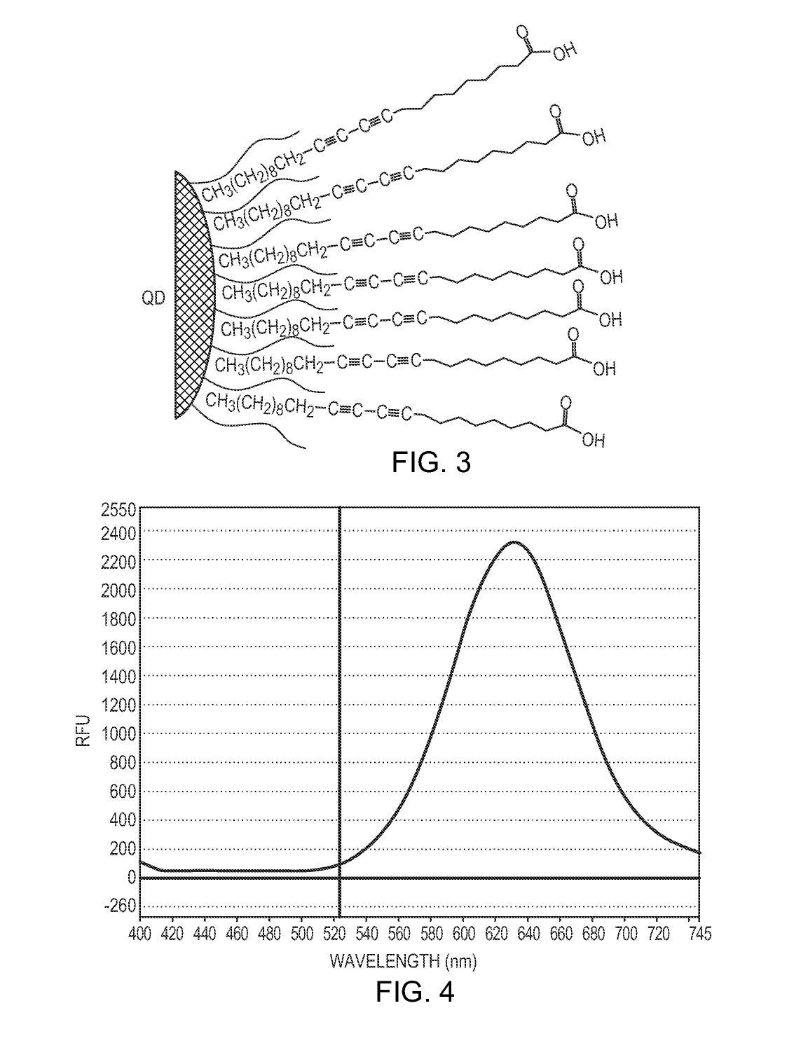

While the inventors do not wish to be bound by any particular theory, it is currently believed that self-assembly of the encapsulating layer around the semiconductor nanoparticle is driven by hydrophobic interactions between the lipophilic regions of the fatty acid/diacetylene molecules, optionally in combination with hydrophobic interactions with existing lipophilic ligands bound to the nanoparticle surface. An example of the latter type of arrangement is depicted schematically in FIG. 3 in which the aliphatic moieties of a plurality of fatty acid molecules incorporating diactylene functional groups have interchelated the lipophilic regions of ligand molecules (shown as black curved lines) already bound to the surface of the quantum dot (QD) nanoparticle. In doing so, the fatty acid/diacetylene molecules have self-assembled into an amphiphilic encapsulating layer which can then bestow aqueous compatibility to the coated nanoparticle and/or be subjected to further chemical modification to incorporate further functionality. In a preferred embodiment of the present invention related to the system depicted in FIG. 3, the carboxylic acid groups of the fatty acid/diacetylene molecules are first replaced with a different water solubilising group, such as polyethylene glycol (PEG) or a derivative thereof, and then brought into contact with the nanoparticles under conditions that are effective to facilitate self-assembly of the encapsulating layer as shown in FIG. 3.

Embodiments of the present invention thus provide nanoparticle compositions incorporating discrete encapsulated nanoparticles, each of which is provided with its own, dedicated surface coating or layer that renders the nanoparticles aqueous compatible and/or suitable for further functionalisation.

In preferred embodiments of various aspects of the present invention, the core of the semiconductor nanoparticle includes a semiconductor material, preferably a luminescent semiconductor material. The semiconductor material may incorporate ions from any one or more of groups 2 to 16 of the periodic table, including binary, ternary and quaternary materials, that is, materials incorporating two, three or four different ions respectively. By way of example, the nanoparticle may incorporate a core semiconductor material, such as, but not limited to, CdS, CdSe, CdTe, ZnS, ZnSe, ZnTe, InP, InAs, InSb, AlP, AIS, AIAs, AISb, GaN, GaP, GaAs, GaSb, PbS, PbSe, Si, Ge and combinations thereof. Nanoparticles according to the present invention preferably possess cores with mean diameters of less than around 20 nm, more preferably less than around 15 nm and most preferably in the range of around 2 to 5 nm.

Nanoparticles that include a single semiconductor material, e.g., CdS, CdSe, ZnS, ZnSe, InP, GaN, etc usually have relatively low quantum efficiencies arising from non-radiative electron-hole recombinations that occur at defects and dangling bonds at the surface of the nanoparticles. In order to at least partially address these issues, the nanoparticle cores may be at least partially coated with one or more layers (also referred to herein as “shells”) of a material different from that of the core, for example a semiconductor material. The material included in the or each shell may incorporate ions from any one or more of groups 2 to 16 of the periodic table. When a nanoparticle has two or more shells, each shell is preferably formed of a different material. In an exemplary core/shell material, the core is formed from one of the materials specified above and the shell includes a semiconductor material of larger band-gap energy and similar lattice dimensions to the core material. Exemplary shell materials include, but are not limited to, ZnS, MgS, MgSe, MgTe and GaN. The confinement of charge carriers within the core and away from surface states provides quantum dots of greater stability and higher quantum yield.

The mean diameter of the nanoparticle may be varied to modify the emission-wavelength. The energy levels and hence the frequency of the nanoparticle fluorescence emission may be controlled by the material from which the nanoparticle is made and the size of the nanoparticle. Generally, nanoparticles made of the same material have a more pronounced red emission the larger the nanoparticle. It is preferred that the nanoparticles have diameters of around 1 to 15 nm, more preferably around 1 to 10 nm. The nanoparticle preferably emits light having a wavelength of around 400 to 900 nm, more preferably around 400 to 700 nm.

Embodiments of further aspects of the present invention relate to methods for the production of nanoparticle compositions.

In accordance with a first further aspect, a method for producing a nanoparticle composition including a semiconductor nanoparticle encapsulated within a self-assembled layer including an amphiphilic cross-linkable multi-unsaturated fatty acid compound or derivative thereof includes
a. providing the semiconductor nanoparticle;
b. providing the amphiphilic fatty acid based compound, and
c. contacting the semiconductor nanoparticle with the amphiphilic fatty acid based compound under conditions suitable to permit the amphiphilic fatty acid based compound to self-assemble so as to form a self-assembled layer encapsulating or at least partially encapsulating the semiconductor nanoparticle.

Embodiments of a further aspect include a method for producing a nanoparticle composition including a semiconductor nanoparticle encapsulated within a self-assembled layer including an amphiphilic cross-linked fatty acid based polymer or derivative thereof. The method includes
a. contacting the semiconductor nanoparticle with the amphiphilic fatty acid based compound, and
b. polymerising the amphiphilic fatty acid based compound.

It is preferred that the fatty acid based compound is provided in at least a 10-fold molar excess, more preferably at least a 100-fold molar excess, and most preferably at least a 1000-fold molar excess compared to the nanoparticles.

Preferably the fatty acid based compound is reacted with a further compound incorporating a hydrophilic group so as to incorporate the hydrophilic group into the fatty acid based compound prior to contacting the nanoparticles with the fatty acid based compound.

Contacting of the nanoparticles with the fatty acid based compound preferably includes incubation at a suitable temperature (e.g., around room temperature or above) and over an appropriate time scale (e.g., around at least around 15 minutes) to facilitate self-assembly of the fatty acid based compound around the nanoparticles to form the encapsulating layer.

Preferably polymerisation is solution based (as opposed to solid state) and/or is effected by exposing the fatty acid based compound to at least one of photoradiation, heat and/or a chemical polymerising agent. In a preferred embodiment, polymerisation is effected by exposing the fatty acid based compound to UV light at around 360 nm.

The exposure may be carried out for at least 1 to 2 minutes, more preferably around 5 minutes. Exposure may be carried out under an inert atmosphere, such as N₂.

Embodiments of a still further aspect include a method for producing a nanoparticle composition comprising a semiconductor nanoparticle encapsulated within a self-assembled layer including an amphiphilic cross-linkable C₈-C₃₆ diacetylene based compound or derivative thereof, the method including
a. providing the semiconductor nanoparticle;
b. providing the amphiphilic diacetylene based compound, and
c. contacting the semiconductor nanoparticle with the amphiphilic diacetylene based compound under conditions suitable to permit the amphiphilic diacetylene based compound to self-assemble so as to form a self-assembled layer encapsulating or at least partially encapsulating the semiconductor nanoparticle.

Embodiments of another aspect include a method for producing a nanoparticle composition comprising a semiconductor nanoparticle encapsulated within a self-assembled layer including an amphiphilic cross-linked C₈-C₃₆ diacetylene based polymer or derivative thereof, the method including
a. contacting the semiconductor nanoparticle with the amphiphilic diacetylene based compound, and
b. polymerising the amphiphilic diacetylene based compound.

The diacetylene based compound may be provided in at least a 10-fold molar excess, more preferably at least a 100-fold molar excess, and most preferably at least a 1000-fold molar excess compared to the nanoparticles.

Preferably the diacetylene based compound is reacted with a further compound incorporating a hydrophilic group so as to incorporate the hydrophilic group into the diacetylene based compound prior to contacting the nanoparticles with the fatty acid based compound.

Contacting the nanoparticles with the diacetylene based compound preferably includes incubation at a suitable temperature (e.g., around room temperature or above) and over an appropriate time scale (e.g., around at least around 15 minutes) to facilitate self-assembly of the diacetylene based compound around the nanoparticles to form the encapsulating layer.

Polymerisation is preferably solution based rather than solid state and may be effected by exposing the diacetylene based compound to at least one of photoradiation, heat and/or a chemical polymerising agent. Preferably polymerisation is effected by exposing the diacetylene based compound to UV light at around 360 nm. Exposure may be carried out for at least 1 to 2 minutes, more preferably for around 5 minutes, and may be carried out under an inert (e.g., N₂) atmosphere.

Typically, as a result of the core and/or shelling procedures employed to produce the core, core/shell or core/multishell nanoparticles, the nanoparticles are at least partially coated with a surface binding ligand, such as myristic acid, hexadecylamine and/or trioctylphosphineoxide. Such ligands are typically derived from the solvent in which the core and/or shelling procedures were carried out. While ligands of this type can increase the stability of the nanoparticles in non-polar media, provide electronic stabilisation and/or negate undesirable nanoparticle agglomeration, as mentioned previously, such ligands typically prevent the nanoparticles from stably dispersing or dissolving in more polar media, such as aqueous solvents.

Preferred embodiments of the present invention provide nanoparticles that are of high quantum yield, stable, and preferably aqueous compatible. Where lipophilic surface binding ligand(s) are coordinated to the surface of the nanoparticle as a result of the core and/or shelling procedures (examples include hexadecylamine, trioctylphosphineoxide, myristic acid), such ligands may be exchanged entirely or partially with the fatty acid or diacetylene based compound, and/or the fatty acid or diacetylene based compound may interchelate with the existing lipophilic surface binding ligands.

In embodiments of aspects of the present invention employing the cross-linkable multi-unsaturated fatty acid, it is preferred that the fatty acid incorporates at least two carbon-carbon double or triple bonds separated by a single carbon-carbon bond. The fatty acid is preferably cross-linkable via the carbon-carbon double or triple bonds.

In a particularly preferred embodiment, the fatty acid incorporates a diacetylene moiety, in which case, it is preferred that the fatty acid is cross-linkable via the diacetylene moiety.

The fatty acid may be photo-, thermally- and/or chemically cross-linkable.

It will be appreciated by the skilled person that fatty acids are saturated or unsaturated aliphatic carboxylic acids. Accordingly, the fatty acid based compound of preferred embodiments of the present invention is preferably linked to or associated with the nanoparticle surface via an aliphatic region of the fatty acid. In this case, the aliphatic region may completely replace, partly replace and/or interchelate other non-fatty acid ligand molecules bound to the nanoparticle surface.

In embodiments of aspects of the present invention employing a diacetylene based polymer, it is preferred that the polymer comprises cross-polymerised repeating units derived from a cross-linkable C₈-C₃₆ diacetylene based compound or derivative thereof.

In embodiments of aspects employing a cross-linkable C₈-C₃₆ diacetylene based compound or derivative thereof, it is preferred that the diacetylene based compound is a C₁₅-C₃₀ diacetylene based compound, or more preferably a C₁₈-C₂₄ diacetylene based compound.

Preferably the fatty acid or diacetylene based compound includes a binding group adapted to be able to bind selectively to a target molecule or binding site, such as a biological molecule or binding site.

In a preferred embodiment the fatty acid or diacetylene based compound has a formula (I)

CH₃(CH₂)ₘ—C≡C—C≡C—(CH₂)ₙ—CO₂X (I)

where m=2 to 20, n=0 to 10, and X is hydrogen or another chemical group.

In further preferred embodiments m=5 to 15, more preferably m=8 to 12 and most preferably m=9. The value for n may be n=6 to 10, or more preferably n=8.

The fatty acid or diacetylene based compound may be derived from a fatty acid compound selected from the group consisting of 10,12-Heptacosadiynoic acid, 10,12-Heptadecadiynoic acid, 10,12-Nonacosadiynoic acid, 10,12-Pentacosadiynoic acid, 10,12-Tricosadiynoic acid, 2,4-Heneicosadiynoic acid, 2,4-Heptadecadiynoic acid, 2,4-Nonadecadiynoic acid, and 2,4-Pentadecadiynoic acid.

It is preferred that the fatty acid or diacetylene based compound incorporates a hydrophilic group which contributes to the amphiphilic character of the compound. Accordingly, in formula (I) X is preferably a hydrophilic group.

The hydrophilic group may be bonded to a carbon atom derived from a carboxylic acid group of the fatty acid compound (as in formula (I) when X is a hydrophilic group) or a terminal carbon atom of the diacetylene compound.

Any suitable hydrophilic group may be incorporated into the fatty acid or diacetylene based compound.

Suitable hydrophilic groups incorporate polyether linkages. Preferably the hydrophilic group is polyethylene glycol or a derivative thereof, which may have an average molecular weight of around 1 to 10,000, more preferably around 3 to 7,000 and most preferably around 5,000.

The hydrophilic group preferably includes a binding group adapted to be able to bind selectively to a target molecule or binding site.

In preferred embodiments, the hydrophilic group may be derived from an organic group and/or may contain one or more heteroatoms (i.e. non-carbon atoms), such as sulfur, nitrogen, oxygen and/or phosphorus. Exemplary hydrophilic groups may be derived from groups including hydroxide, alkoxide, carboxylic acid, carboxylate ester, amine, nitro, polyethyleneglycol, sulfonic acid, sulfonate ester, phosphoric acid and phosphate ester.

While any appropriate hydrophilic group may be employed, in a preferred embodiment the hydrophilic group is a charged or polar group, such as a hydroxide salt, alkoxide salt, carboxylate salt, ammonium salt, sulfonate salt or phosphate salt.

The carboxylate group may also provide appropriate chemical functionality to participate in coupling/crosslinking reaction(s), such as the carbodiimide mediated coupling between a carboxylic acid and an amine, or to be coupled to other species including proteins, peptides, antibodies, carbohydrates, glycolipids, glycoproteins and/or nucleic acids.

It will be appreciated that the scope of the present invention is not limited to the preferred embodiments described above and that the embodiments may be modified without departing from the basic concept underlying each aspect of the present invention defined above.

The invention will now be further described, by way of example only, with reference to the following non-limiting Examples:

### EXAMPLES

### Example 1

### Functionalisation of Quantum Dots Using a PEGylated Diacetylene Compound

A sample of cadmium-free quantum dots (QDs) was functionalised to incorporate a PEGylated polydiacetylene surface capping agent as follows.

The surface capping agent was first prepared by production of a suitable polymerisable monomer. The carboxyl end of 10,12-Tricosadiynoic acid was coupled to equal stoichiometric amounts of CH₃—O-PEG5000—NH₂ using DCC coupling. The resulting PEGylated diacetylene compound was purified by repeated washing and precipitation using chloroform. The chemical structure of the product was confirmed by NMR and showed that the reaction went to completion.

The pre-prepared diacetylene monomer was then added to the sample of cadmium-free InP/ZnS QDs. To the InP/ZnS QDs with a myristic acid capping layer in chloroform was added a 1000-fold (monomer/dot molar ratio) of the PEGylated diacetylene monomer. The resulting solution was briefly vortex-mixed and then incubated at 50° C. for 30 minutes.

Polymerisation of the PEGylated diacetylene monomer bound to the InP/ZnS QDs was then effected by irradiating the solution containing the coated QDs with UV light at 360 nm for 5 minutes under N₂ gas. Following irradiation, the solution was stored at room temperature over night (˜15 h).

A stable aqueous solution of the QDs was then prepared as follows. To the QD-containing solution was added non-functionalized PEG 3000 at a ratio of 1% w/volume. The resulting clear solution was dried using a rotary evaporator. To the dried residue, a sufficient amount of borate buffer (50 mM sodium borate, pH8.0) was added. The mixture was slowly swirled until the residue was completely dissolved to give an aqueous solution of the QDs capped with the PEGylated diacetylene polymer. A final preparation of the QDs was purified from excess PEG and any non-reacted monomer by using a standard gel filtration column.

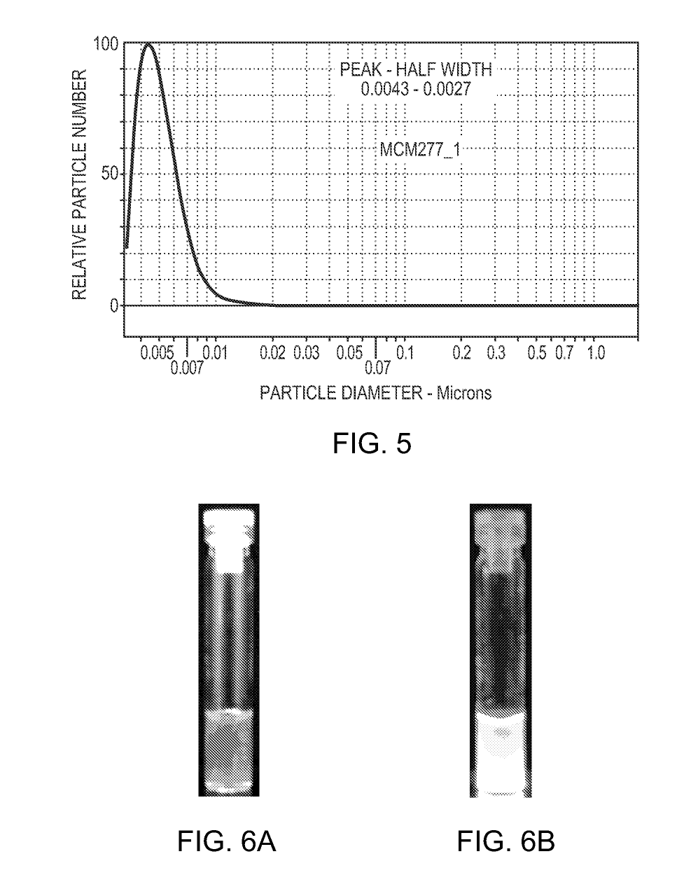

The emission and size properties of the water soluble InP/ZnS-polydiacetylene QDs produced according to the above procedure are shown in FIGS. 4 and 5, respectively. As can be seen, the capped QDs emitted at approximately 630 nm and possessed a narrow particle size dispersity. The high level of aqueous solubility exhibited by the QDs is demonstrated with reference to FIGS. 6a and 6b, which are photographs of the sample taken under ambient light (FIG. 6a) and UV light at 360 nM (FIG. 6b) and show that the solutions were transparent.

### Example 2

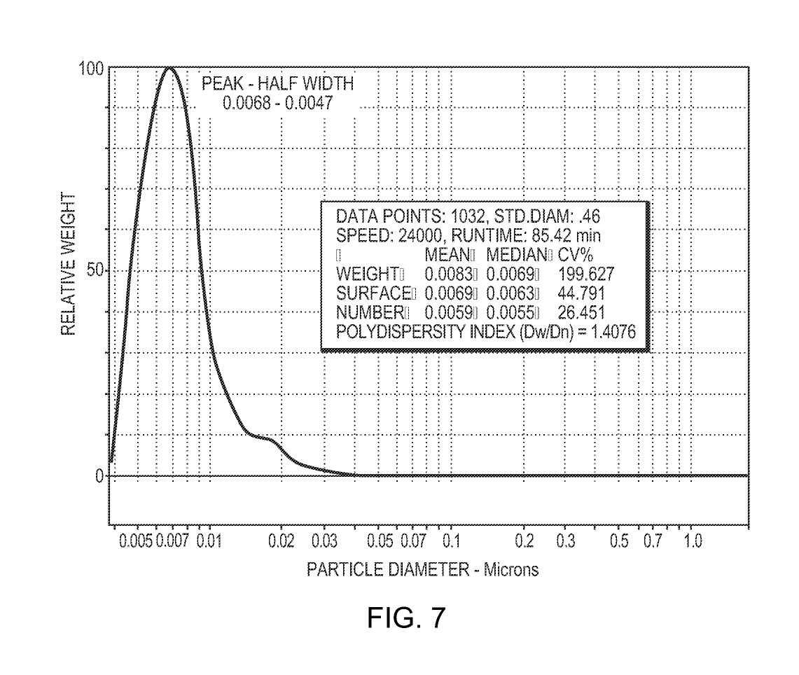

A further sample of cadmium-free quantum dots (QDs) was functionalised to incorporate a polydiacetylene surface capping agent using similar methods to those described above in Example 1. The particle size dispersity of the encapsulated QDs is illustrated in FIG. 7 which depicts data captured using a method combining both dynamic light scatter and ultracentrifugation (CPS). The strong narrow peak at 6.8 nm illustrates the low particle size dispersity across the population of encapsulated QDs and supports the conclusion that the methods of the present invention result in discrete encapsulated QDs, each provided with its own self-assembled encapsulating layer.

It will be seen that the techniques described herein provide a basis for improved production of nanoparticle materials. The terms and expressions employed herein are used as terms of description and not of limitation, and there is no intention in the use of such terms of and expressions of excluding any equivalents of the features shown and described or portions thereof. Instead, it is recognized that various modifications are possible within the scope of the invention claimed.

What is claimed is:

1. A nanoparticle composition comprising:
a semiconductor nanoparticle encapsulated within a self-assembled layer comprising an amphiphilic cross-linkable multi-unsaturated fatty acid based compound or derivative thereof.

2. A nanoparticle composition according to claim 1, wherein the cross-linkable multi-unsaturated fatty acid incorporates at least two carbon-carbon double or triple bonds separated by a single carbon-carbon bond.

3. A nanoparticle composition according to claim 1, wherein the fatty acid incorporates a diacetylene moiety.

4. A nanoparticle composition according to claim 1, wherein the fatty acid is associated with the nanoparticle surface via an aliphatic region of the fatty acid.

5. A nanoparticle composition according to claim 1, wherein the fatty acid based compound comprises a binding group adapted to be able to bind selectively to a target molecule or binding site.

6. A nanoparticle composition according to claim 1, wherein the fatty acid based compound has a formula (I)
CH₃(CH₂)ₘ—C≡C—C≡C—(CH₂)ₙ—CO₂X (I)
where m=2 to 20, n=0 to 10, and X is hydrogen or another chemical group.

7. A nanoparticle composition according to claim 6, wherein X is a hydrophilic group.

8. A nanoparticle composition according to claim 1, wherein the fatty acid based compound is derived from a fatty acid compound selected from the group consisting of 10,12-Heptacosadiynoic acid, 10,12-Heptadecadiynoic acid, 10,12-Nonacosadiynoic acid, 10,12-Pentacosadiynoic acid, 10,12-Tricosadiynoic acid, 2,4-Heneicosadiynoic acid, 2,4-Heptadecadiynoic acid, 2,4-Nonadecadiynoic acid, and 2,4-Pentadecadiynoic acid.

9. A nanoparticle composition according to claim 1, wherein the fatty acid based compound incorporates a hydrophilic group.

10. A nanoparticle composition according to claim 8 or 9, wherein the hydrophilic group incorporates polyether linkages.

11. A nanoparticle composition according to claim 8 or 9, wherein the hydrophilic group is polyethylene glycol or a derivative thereof.

12. A nanoparticle composition according to claim 8 or 9, wherein the hydrophilic group comprises a binding group adapted to be able to bind selectively to a target molecule or binding site.

13. A nanoparticle composition comprising:
a semiconductor nanoparticle encapsulated within a self-assembled layer comprising an amphiphilic cross-linked fatty acid based polymer or derivative thereof.

14. A nanoparticle composition according to claim 13, wherein the fatty acid based polymer comprises cross-polymerised repeating units derived from a cross-linkable multi-unsaturated fatty acid based compound or derivative thereof.

15. A nanoparticle composition according to claim 13, wherein the fatty acid based polymer incorporates a diacetylene moiety.

16. A nanoparticle composition comprising:
a semiconductor nanoparticle encapsulated within a self-assembled layer comprising an amphiphilic cross-linkable C₈-C₃₆ diacetylene based compound or derivative thereof.

17. A nanoparticle composition according to claim 16, wherein the diacetylene based compound incorporates a hydrophilic group.

18. A nanoparticle composition according to claim 17, wherein the hydrophilic group is bonded to a terminal carbon atom of the diacetylene compound.

19. A nanoparticle composition according to claim 17, wherein the hydrophilic group incorporates polyether linkages.

20. A nanoparticle composition according to claim 17, wherein the hydrophilic group is polyethylene glycol or a derivative thereof.

21. A nanoparticle composition according to claim 16, wherein the diacetylene based compound comprises a binding group adapted to be able to bind selectively to a target molecule or binding site.

22. A nanoparticle composition comprising:
a semiconductor nanoparticle encapsulated within a self-assembled layer comprising an amphiphilic cross-linked C₈-C₃₆ diacetylene based polymer or derivative thereof.

23. A nanoparticle composition according to claim 22, wherein the diacetylene based polymer comprises cross-polymerised repeating units derived from a cross-linkable C₈-C₃₆ diacetylene based compound or derivative thereof.

24. A nanoparticle composition according to claim 1 or 16, wherein the nanoparticle is a core, core/shell or core/multishell nanoparticle.

25. A method for producing a nanoparticle composition comprising semiconductor nanoparticles encapsulated within a self-assembled layer comprising an amphiphilic cross-linkable multi-unsaturated fatty acid compound or derivative thereof, the method comprising
a. providing the semiconductor nanoparticles;
b. providing the amphiphilic fatty acid based compound, and
c. contacting the semiconductor nanoparticles with the amphiphilic fatty acid based compound under conditions suitable to permit the amphiphilic fatty acid based compound to self-assemble so as to form a self-assembled layer encapsulating or at least partially encapsulating each semiconductor nanoparticle.

26. A method according to claim 25, wherein the fatty acid based compound is provided in at least a ten-fold molar excess compared to the nanoparticles.

27. A method according to claim 25, wherein the fatty acid based compound is reacted with a further compound incorporating a hydrophilic group so as to incorporate the hydrophilic group into the fatty acid based compound prior to contacting the nanoparticles with the fatty acid based compound.

28. A method for producing a nanoparticle composition comprising a semiconductor nanoparticle encapsulated within a self-assembled layer comprising an amphiphilic cross-linked fatty acid based polymer or derivative thereof, the method comprising
a. contacting the semiconductor nanoparticle with the amphiphilic fatty acid based compound, and
b. polymerising the amphiphilic fatty acid based compound.

29. A method according to claim 28, wherein polymerisation is effected by exposing the fatty acid based compound to at least one of photoradiation, heat, or a chemical polymerising agent.

30. A method for producing a nanoparticle composition comprising semiconductor nanoparticles encapsulated within a self-assembled layer comprising an amphiphilic cross-linkable C₈-C₃₆ diacetylene based compound or derivative thereof, the method comprising
a. providing the semiconductor nanoparticles;
b. providing the amphiphilic diacetylene based compound, and
c. contacting the semiconductor nanoparticles with the amphiphilic diacetylene based compound under conditions suitable to permit the amphiphilic diacetylene based compound to self-assemble so as to form a self-assembled layer encapsulating or at least partially encapsulating each semiconductor nanoparticle.

31. A method according to claim 30, wherein the diacetylene based compound is provided in at least a ten-fold molar excess compared to the nanoparticles.

32. A method according to claim 30, wherein the diacetylene based compound is reacted with a further compound incorporating a hydrophilic group so as to incorporate the hydrophilic group into the diacetylene based compound prior to contacting the nanoparticles with the fatty acid based compound.

33. A method for producing a nanoparticle composition comprising a semiconductor nanoparticle encapsulated within a self-assembled layer comprising an amphiphilic cross-linked C₈-C₃₆ diacetylene based polymer or derivative thereof, the method comprising
a. contacting the semiconductor nanoparticle with the amphiphilic diacetylene based compound, and
b. polymerising the amphiphilic diacetylene based compound.

34. A method according to claim 33, wherein polymerisation is effected by exposing the diacetylene based compound to at least one of photoradiation, heat, or a chemical polymerising agent.
